(19) United States
(12) Patent Application Publication
(10) Pub. No.: US 2010/0309098 A1
(43) Pub. Date: Dec. 9, 2010

(54) IMAGE DISPLAY APPARATUS USING ORGANIC EL DEVICE

(75) Inventors: Rei Kurashima, Mobara-shi (JP); Koichi Fukuda, Tokyo (JP)

Correspondence Address: FITZPATRICK CELLA HARPER & SCINTO, 1290 Avenue of the Americas, NEW YORK, NY, 10104-3800, US

(73) Assignee: CANON KABUSHIKI KAISHA, Tokyo (JP)

(21) Appl. No.: 12/782,854

(22) Filed: May 19, 2010

(30) Foreign Application Priority Data
Jun. 3, 2009 (JP) 2009-134064

(51) Int. Cl. G09G 3/30

(52) U.S. Cl. 345/32

(57) ABSTRACT

Provided is an image display apparatus which achieves robustness of display characteristics (luminance and chromaticity) with respect to a film thickness unevenness, and in which an arbitrary one of pixels includes pixel groups (A and B) which have two characteristics and have a combination of film thicknesses in which: one of the film thicknesses is smaller and another one of the film thicknesses is larger than a film thickness at a peak of a curve in a protruding shape given by an intensity variation of emission luminance with respect to a film thickness variation of the pixel; and the one of the film thicknesses is smaller and the another one of the film thicknesses is larger than a film thickness at a peak of a curve in a protruding shape given by a chromaticity variation of at least one component of chromaticity (CIE x, CIE y) with respect to the film thickness variation of the pixel.

### BACKGROUND OF THE INVENTION

1. Field of the Invention

The present invention relates to an image display apparatus in which an organic EL device is disposed at each pixel, and more particularly, to an image display apparatus using an organic EL device having a resonator structure for reinforcing a specific wavelength in each pixel.

2. Description of the Related Art

An organic EL device is a self-emission device utilizing a principle of an emission layer made of an organic material that emits light by recombination energy between holes injected from an anode and electrons injected from a cathode when an electric field is applied. Since the low voltage drive organic EL device as a stack-type device was reported by C. W. Tang et al., studies about the organic EL device made of an organic material have been performed actively.

In addition, the organic EL device has a wide viewing angle and sufficient moving picture response because of its self-emission property, and hence has ideal characteristics as a display device. In particular, because of its thin shape, light weight, and high impact resistance, the organic EL device has been developed as a display device for mobile applications in recent years.

The conventional organic EL device controls light generated in the emission layer by utilizing the resonator structure so as to improve color purity of an emission color and to enhance light extraction efficiency (see WO01/39554A). However, if the resonator structure is provided to the organic EL device, very high accuracy of an optical path length, i.e., a film thickness is required so that resonator performance is exerted without an unevenness. Here, a conventional basic resonator structure is described. FIG. 15 is a schematic cross sectional view illustrating a conventional basic resonator structure in Conventional Example 1. In FIG. 15, the conventional basic resonator structure includes a substrate 1601, a first electrode (reflective film) 1602, a buffer layer 1603, a hole-transporting layer 1604, an organic emission layer 1605, and a translucent reflective layer (translucent reflective film) 1606. Further, in FIG. 15, the conventional basic resonator structure includes a second electrode 1607, a light emission position is represented by reference numeral 1608, and an optical length L of a resonant portion is represented by reference numeral 1609.

As illustrated in FIG. 15, the conventional resonator structure has the organic emission layer 1605 sandwiched between the translucent reflective layer (translucent reflective film) 1606 and the first electrode (reflective film) 1602. Then, the optical length L 1609 of the resonant portion between the translucent reflective layer (translucent reflective film) 1606 and the first electrode (reflective film) 1602 is controlled. If the optical length L to an ordinary degree that satisfies a resonance condition is converted into a film thickness, the film thickness is approximately several ten to several hundred nanometers, which is very thin. In addition, if an image display apparatus is constituted by using the organic EL device for each pixel, it is easily assumed that the permissible film thickness unevenness is very small in the entire region of the image display considering the in-plane unevenness of color purity and light extraction efficiency.

It is needless to say that it is important and necessary to reduce the film thickness unevenness in the film forming process as a countermeasure against these technical problems. However, even if emission luminance is affected by the film thickness unevenness, the emission luminance may be corrected by a drive method. However, it is necessary to read luminance information of each pixel with respect to input power, and to store a corrected data table in a prepared memory. This may cause increases in number of new steps and members resulting in high cost as a demerit.

To solve these technical problems, there is proposed a structure in which one pixel has regions having different resonator lengths or a structure in which the resonator length is different between neighboring pixels (see Japanese Patent Application Laid-Open No. 2007-234581). FIG. 16 is a schematic cross sectional view illustrating a conventional basic resonator structure in Conventional Example 2. In FIG. 16, the conventional basic resonator structure includes a pixel 1701, a neighboring pixel 1702, a substrate 1703, a reflective electrode 1704, a transparent electrode 2 1705, a transparent electrode 1 1706, and multiple organic compound layers 1707. Further, the conventional basic resonator structure includes a second electrode 1708, an adhesive layer 1709, a color filter 1710, a sealing substrate 1711, and a protective film 1712. In addition, film thicknesses of RGB pixels are represented by reference numerals 1713 to 1718, respectively. In the example illustrated in FIG. 16, two types of resonator lengths L1 and L2 are set as film thickness structures of RGB pixels as follows.

L1=Lave+ΔL (1)

L2=Lave−ΔL (2)

(2−Lave)/λ+Φ/(2π)=m (3)

In the expressions, Lave denotes an average optical length between the optical length L1 and the optical length L2, Φ denotes a sum of a phase shift Φ1 of reflection light generated in the reflective electrode and a phase shift Φ2 of reflection light generated in the second electrode (Φ=Φ1+Φ2) (radians), λ denotes a peak wavelength of a spectrum of light to be extracted from the second electrode, and m is an integer in which Lave becomes positive.

In this way, two peaks shifted before and after the interference peak wavelength by the same degree are used as average peaks, and hence a peak variation with respect to the film thickness unevenness may be reduced. As a result, even if some film thickness unevenness occurs, robustness may be secured for a part of light-emitting characteristics.

As described above, in the image display apparatus using the organic EL device having the resonator structure as a pixel, a film thickness unevenness in the film forming process cannot be ignored so that an unevenness of display characteristics occurs.

For instance, in the image display apparatus using the organic EL device having the resonator structure disclosed in WO01/39554A as a pixel, it is predicted that film thickness unevenness in the film forming process becomes display characteristic unevenness in the image display region.

In order to solve this problem, Japanese Patent Application Laid-Open No. 2007-234581 describes the method in which two types of light-emitting devices having different device film thicknesses shifted from the device film thickness L satisfying the interference condition by ±ΔL are combined and used. Thus, the interference characteristic with respect to the film thickness unevenness may be averaged, and hence the display characteristic unevenness may be suppressed. However, luminance variation is large before and after an extreme value satisfying the interference condition, and chromaticity variation also increases along with the interference characteristic. In this way, if only the interference condition is noted, there is a case where the display unevenness with respect to the chromaticity variation cannot be suppressed.

### SUMMARY OF THE INVENTION

In view of the above-mentioned problems, an object of the present invention is to provide a structure in which display characteristics (luminance and chromaticity) with respect to a film thickness unevenness becomes robust, and to provide an image display apparatus using the structure.

According to the present invention, there is provided an image display apparatus using an organic EL device in which an organic compound layer are sandwiched between a reflective electrode and a transparent electrode so that emitted light interferes between the reflective electrode and the transparent electrode. Further, an arbitrary one of emission pixels includes pixel groups (A and B) which have two characteristics and have a combination of film thicknesses in which: one of the film thicknesses is smaller and another one of the film thicknesses is larger than a film thickness at a peak of a curve in a protruding shape given by an intensity variation of emission luminance with respect to a film thickness variation of the emission pixel; and the one of the film thicknesses is smaller and the another one of the film thicknesses is larger than a film thickness at a peak of a curve in a protruding shape given by a chromaticity variation of at least one component of chromaticity (CIE x, CIE y) with respect to the film thickness variation of the emission pixel.

With the image display apparatus using the organic EL device of the present invention, a complementary effect is obtained between neighboring pixels of the same color, and hence the influence of the film thickness unevenness on the display characteristic in the film forming process may be reduced. Therefore, yields of the image display apparatus using the organic EL device are improved so as to significantly contribute to reduction in cost.

Further features of the present invention will become apparent from the following description of exemplary embodiments with reference to the attached drawings.

### BRIEF DESCRIPTION OF THE DRAWINGS

FIG. 1 is a cross sectional view of pixels each of which is an organic EL device according to Example 1 of the present invention.

FIG. 2 is an arrangement diagram of the organic EL devices according to Example 1 of the present invention.

FIG. 3 is a light-emitting characteristic diagram of a Ref., a pixel A and a pixel B in the organic EL device according to Example 1 of the present invention.

FIG. 4 is a circuit diagram illustrating an example of an active matrix circuit for driving the organic EL device.

FIG. 5 is a cross sectional view of a pixel of the organic EL device.

FIGS. 6A and 6B are explanatory diagrams of a film thickness unevenness in a display region (FIG. 6A is a cross sectional view, and FIG. 6B is a top view).

FIGS. 7A and 7B are explanatory graphs of Correlation Example 1 of the pixel A and the pixel B when a film thickness varies (FIG. 7A illustrates an increase in film thickness, and FIG. 7B illustrates a decrease in film thickness).

FIG. 8 is an explanatory diagram of an example of the film thickness unevenness in the display region when the present invention is applied.

FIGS. 9A and 9B are explanatory graphs of Correlation Example 2 of the pixel A and the pixel B when the film thickness varies (FIG. 9A illustrates an increase in film thickness, and FIG. 9B illustrates a decrease in film thickness).

FIG. 10 is a contour graph of film thicknesses of two pixels.

FIG. 11 is a contour graph of film thicknesses of pixels when the pixel A and the pixel B are set with respect to different extreme values.

FIG. 12 is an explanatory diagram of a plane arrangement example of a pixel group A and a pixel group B (stripe arrangement).

FIG. 13 is an explanatory diagram of a plane arrangement example of the pixel group A and the pixel group B (delta arrangement).

FIG. 14 is an explanatory diagram of chemical structural formulas of organic materials that are used in an embodiment of the present invention.

FIG. 15 is a cross sectional view of a pixel of Conventional Example 1.

FIG. 16 is a cross sectional view of a pixel of Conventional Example 2.

### DESCRIPTION OF THE EMBODIMENT

An image display apparatus using an organic EL device according to an embodiment of the present invention includes emission pixels. The emission pixel refers to a pixel in which an organic compound layer are sandwiched between a reflective film (reflective electrode) and a translucent reflective film (transparent electrode) so that emitted light interferes between the reflective film and the translucent reflective film (see FIG. 5). Further, an arbitrary one of the emission pixels includes pixel groups (A and B) which have two characteristics and have a combination of film thicknesses in which one of the film thicknesses is smaller and another one of the film thicknesses is larger than a film thickness at a peak of a curve in a protruding shape given by an intensity variation of emission luminance with respect to a film thickness variation of the emission pixel; and the one of the film thicknesses is smaller and the another one of the film thicknesses is larger than a film thickness at a peak of a curve in a protruding shape given by a chromaticity variation of at least one component of chromaticity (CIE x, CIE y) with respect to the film thickness variation of the emission pixel.

Here, the film thickness at the peak of the curve in the protruding shape given by the intensity variation of the emission luminance may be one type of film thickness satisfying an interference condition or may be two types of different film thicknesses satisfying the interference condition. In addition, the pixel groups having the two characteristics may be arranged alternately in one of a checkered pattern and a pattern similar to the checkered pattern in each emission pixel in plan view. In addition, the chromaticity variation of the at least one component of the chromaticity (CIE x, CIE y) may be a variation in CIE y of a green color pixel. The detail is described later. Note that the interference condition means the above-mentioned equation (3).

In order to display characters and graphics by using an organic EL device, it is necessary to arrange devices in matrix to form a display apparatus. The method of arranging the organic EL devices in matrix commonly include a so-called XY passive matrix time-division duty drive method and active drive method in which an active device such as a thin film transistor (TFT) is arranged in each pixel. The passive matrix method is disadvantageous in durability because it is necessary to cause a large quantity of current to flow through the devices so as to obtain sufficient luminance. At present, it is considered that the active drive type is the most practical in use, but the present invention is not limited to the active drive type.

Hereinafter, the embodiment of the image display apparatus using the organic EL device according to the present invention is described with reference to the drawings. Note that the pixel and the pixel group may be denoted by the same reference numeral in the following description.

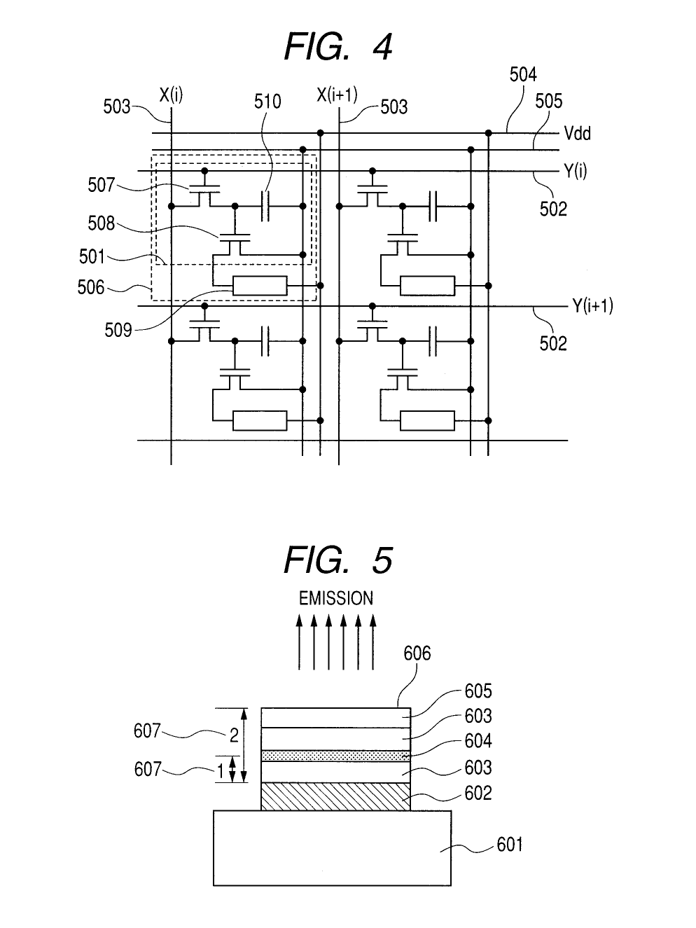

FIG. 4 is a circuit diagram illustrating a structural example of the image display apparatus according to the embodiment of the present invention, such as an active matrix image display apparatus. In the example illustrated in FIG. 4, a large number of pixel circuits 501 are arranged in matrix so as to constitute a display region. Here, for a simple illustration, a pixel arrangement of two rows and two columns, i.e., i and (i+1) rows and i and (i+1) columns is exemplified. In this display region, scanning signals Y(i) and Y(i+1) are supplied to the individual pixel circuits 501 sequentially. Thus, scanning lines 502 for selecting a row of pixels 506 and signal lines 503 for supplying individual pixels with image data, e.g., luminance data X(i) and X(i+1) are laid. In the following description, the pixel (i, i) of the i-th row and the i-th column is exemplified as the pixel circuit 501. However, the pixel circuits 501 of other pixels have completely the same circuit structure. Note that the pixel circuit is not limited to this circuit example.

This pixel circuit 501 includes a selection device portion 507 for selecting a pixel, a sustaining capacitor portion 510 for sustaining a gate voltage of a drive device portion 508, and the drive device portion 508 for driving an organic EL device 509. Note that a unit of the selection device portion 507 and the drive device portion 508 is integrally referred to as a pixel transistor. Then, luminance data is supplied as a voltage from the signal line 503, and hence current according to the data voltage flows in the organic EL device 509.

As a specific connection relationship, an anode of the organic EL device 509 is connected to a power supply line 504 (power supply voltage Vdd). The drive device portion 508 is connected between a cathode of the organic EL device 509 and a ground line 505. The sustaining capacitor portion 510 is connected between a gate of the drive device portion 508 and the ground line 505. The selection device portion 507 is connected between the signal line 503 and the gate of the drive device portion 508, and a gate thereof is connected to the scanning line 502. The selection device portion 507 and the drive device portion 508 are constituted of a thin film transistor (TFT), and an amorphous silicon semiconductor, a polysilicon semiconductor, a low temperature polysilicon semiconductor, or a transparent oxide semiconductor may be selected according to necessary current quantity and a sub pixel size.

Hereinafter, a target pixel (a target pixel group) is defined as a pixel (a pixel group) A, and a pixel (a pixel group) of the same color adjacent to the pixel (the pixel group) A is defined as a pixel (a pixel group) B. In addition, in the following description, any one of the expressions of “pixel” and “pixel group” is used according to contents appropriately. In addition, the pixel film thickness means a pixel film thickness 607 between interfaces necessary for multiple interference and reflection within the organic EL device with respect to light generated in the organic EL device as illustrated in FIG. 5. FIG. 5 is a cross sectional view of a pixel of the organic EL device. Note that in FIG. 5, a substrate is represented by reference numeral 601; a reflective electrode, 602; an organic compound layer, 603; an emission layer, 604; a transparent electrode, 605; an interface with air, 606; and a pixel film thickness, 607.

This organic EL device has two pixel film thicknesses 607 (pixel film thickness 1 for n-th order resonance and pixel film thickness 2 for (n+1)th order resonance), but it is supposed that there is one pixel film thickness in the following description of a principle. Incidentally, the present invention includes a case where one organic EL device in each pixel comprises two regions having different pixel film thicknesses in the in-plane direction. In this case, one region corresponds to pixel (pixel group) A, and the other region corresponds to pixel (pixel group) B. And, the pixel A and the pixel B are driven by a common pixel circuit.

In addition, as an index for comparing emission efficiency of light-emitting devices with different colors, “luminance/CIE y” is defined. CIE y is a y value in an xy chromaticity diagram that is defined by the CIE 1931 standard colorimetric system. If the luminance is the same as a stimulus value Y, the “luminance/CIE y” becomes a sum of tristimulus values based on y=Y/(X+Y+Z). If the CIE y is different between light-emitting devices with the same luminance, the “luminance/CIE y” means that the drive power is different by the difference thereof. In other words, if the “luminance/CIE y” value is higher, the emission efficiency becomes relatively higher, and hence the drive power for emitting light of the same luminance becomes relatively low. When the device is controlled actually, the power is controlled. Therefore, it is convenient to consider by the “luminance/CIE y”. Hereinafter, any one of “luminance” and “luminance/CIE y” is used according to description. Although the xy chromaticity diagram of CIE-XYZ colorimetric system is often used as the chromaticity expression, the CIELUV space or the CIELAB space may be used according to purpose.

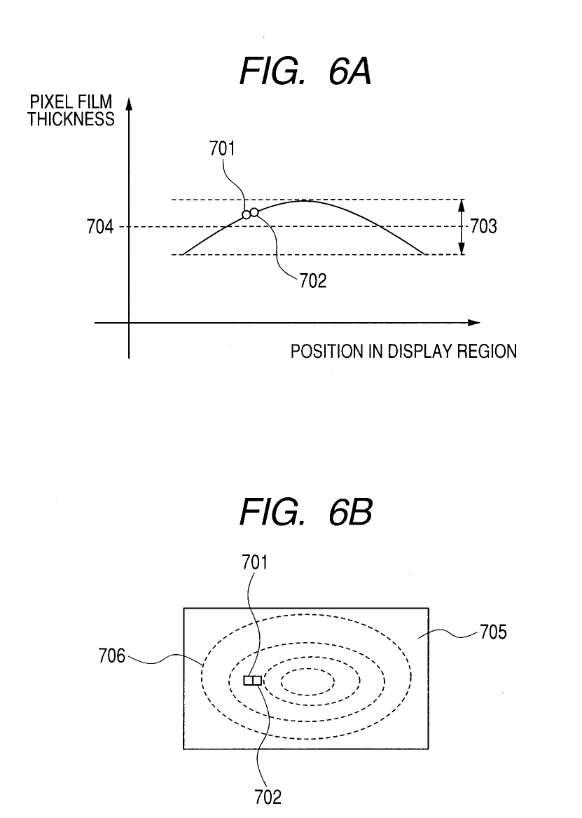

FIGS. 6A and 6B are explanatory diagrams for illustrating an occurrence example of a film thickness unevenness of the organic EL device in the display region of the image display apparatus. FIG. 6A is a cross sectional view, and FIG. 6B is a top view. In FIGS. 6A and 6B, a pixel A is represented by reference numeral 701; a pixel B, 702; a film thickness variation (film thickness unevenness), 703; a target film thickness, 704; the display region, 705; and an equivalent film thickness line, 706.

In order to form a film of an organic compound layer on the substrate, it is common to adopt the method of preparing an organic material as a raw material in a metal melting pot, heating the melting pot in a vacuum chamber, and sublimating or evaporating the organic material. This film forming method has a tendency that the film thickness becomes larger as the distance between the evaporation source and the substrate is smaller while the film thickness becomes smaller as the distance is larger. This tendency depends on directivity of the evaporation and a diffusion distance of the evaporation material, and reproducibility thereof is relatively high. Therefore, if the evaporation source is located at the center of the substrate, the film thickness unevenness is apt to occur as illustrated in FIGS. 6A and 6B.

In addition, the electrode layer or the like made of an inorganic film is usually formed by sputtering film forming. For instance, in the case of face target RF sputtering film forming, there is a strong correlation between a plasma density distribution and a film forming unevenness. The plasma density distribution depends on an apparatus structure, and reproducibility thereof is also relatively high. The film thickness unevenness in the sputtering film forming is smaller than that in vacuum heat evaporation, but is generally in the range from ±3 to ±5% in the entire region.

As being clear from FIG. 6A, a difference in pixel film thickness is small between the neighboring pixels A and B. Therefore, a difference in light-emitting characteristics due to the same rarely becomes a problem. The problem is a gradual film thickness unevenness in a display region scale. In particular, if the resonator structure is used in the organic EL device, a film thickness unevenness at a ±5% level of an average film thickness in the plane is sufficiently regarded as a variation in luminance characteristic or chromaticity characteristic.

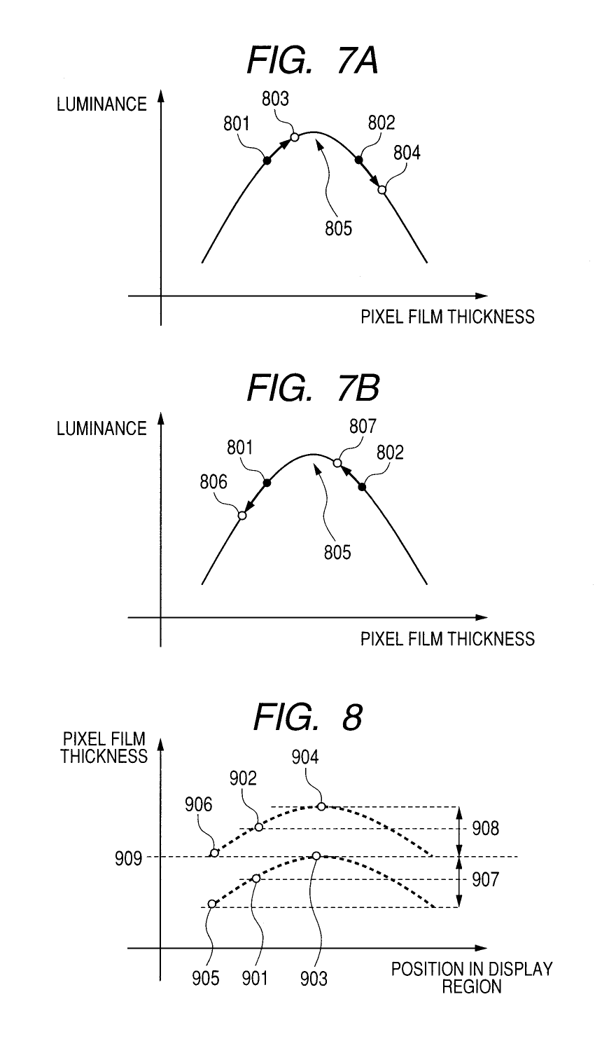

FIGS. 7A and 7B are explanatory graphs of Correlation Example 1 of the pixel A and the pixel B when the film thickness varies, illustrating the case where the luminance is made robust with respect to the film thickness unevenness. In FIGS. 7A and 7B, the pixel A is represented by reference numeral 801; the pixel B, 802; a pixel A′, 803; a pixel B′, 804; a maximum value, 805; a pixel A″, 806; and a pixel B″, 807.

First, if the luminance is to be made robust, the pixel film thicknesses of the pixel groups A 801 and B 802 are constituted so that the luminance varies in a complementary manner with respect to the film thickness variation. Here, to vary the luminance in a complementary manner means that when the pixel film thickness increases (or decreases), for example, the luminance of the pixel A 801 increases (or decreases) so that the characteristic varies to be the pixel A′ 803 (A″ 806). In addition, it means that the luminance of the pixel B 802 decrease (increases) so that the characteristic varies to be the pixel B′ 804 (B″ 807). Even if the pixel film thickness increases or decreases, if the pixel A 801 and the pixel B 802 maintain the relationship in the variation, the average luminance characteristics of the pixel A 801 and the pixel B 802 have a small variation with respect to the film thickness variation, which means that the luminance is made robust. In other words, in order that the luminance values of the pixel group A 801 and the pixel group B 802 have a complementary characteristic, it is necessary that in one of the pixel groups A 801 and B 802, the luminance increases while in the other, the luminance decreases when the pixel film thickness varies.

In order to realize the relationship between the pixel group A and the pixel group B, two combinations having the pixel film thickness variations as illustrated in FIG. 8 are necessary. FIG. 8 is an explanatory diagram of an example of the film thickness unevenness in the display region when the present invention is applied. In FIG. 8, the pixel A is represented by reference numeral 901; the pixel B, 902; the pixel A′, 903; the pixel B′, 904; the pixel A″, 905; the pixel B″, 906; the film thickness variations (film thickness unevennesses), 907 and 908; and the pixel film thickness that gives the maximum value of the luminance or its vicinity, 909.

In order to make the film thickness unevennesses (907 and 908) of the pixel A 901 and the pixel B 902 substantially similar to each other, the film forming quantity only needs to be adjusted to be different in the same film forming step. The film thickness unevennesses (907 and 908) are substantially similar to each other, and hence even if a position of the target pixel (pixel A 901) in the display region is moved, a difference in pixel film thickness between the pixel group A 901 and the pixel group B 902 becomes substantially constant. Then, the pixel film thicknesses thereof are determined so that the maximum value of luminance is sandwiched between the pixel A 901 and the pixel B 902. Thus, a combination of the pixel A 901 and the pixel B 902 having the complementary function may be realized.

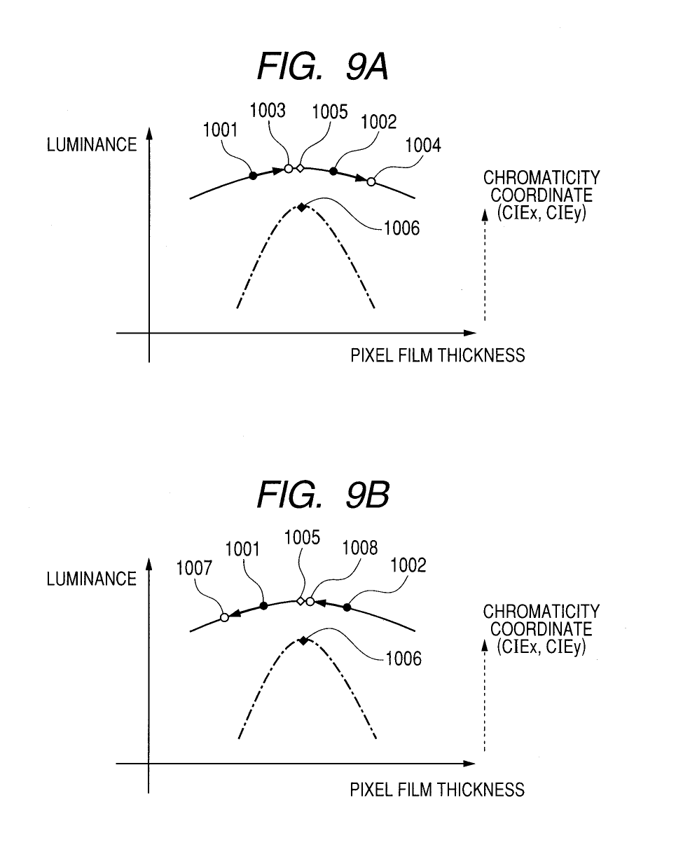

However, not only robustness of luminance but also robustness of chromaticity needs to be actually considered. The case where luminance and chromaticity are made robust with respect to the film thickness unevenness is described with reference to FIGS. 9A and 9B. FIGS. 9A and 9B are explanatory graphs of Correlation Example 2 of the pixel A and the pixel B when the film thickness varies. In FIGS. 9A and 9B, the pixel A is represented by reference numeral 1001; the pixel B, 1002; the pixel A′, 1003; the pixel B′, 1004; the maximum value, 1005; a target chromaticity, 1006; the pixel A″, 1007; and the pixel B″, 1008.

For instance, it is supposed that the target chromaticity 1006 has a sharp maximum shape when a graph of the chromaticity coordinates with respect to the pixel film thickness is plotted. In this case, using a region in which the luminance varies gradually, the pixel (group) A 1001 and the pixel (group) B 1002 are set so as to sandwich the maximum value of the target chromaticity 1006. In order to select the region in which the luminance varies gradually, the film thickness of the structure that gives the maximum interference luminance and its vicinity needs to be avoided.

Then, even if the pixel film thickness increases or decreases, an average luminance of the pixel A 1001 and the pixel B 1002 is substantially constant so that any one of the pixel A 1001 and the pixel B 1002 becomes close to the target chromaticity 1006. By setting the pixel A 1001 and the pixel B 1002 in this way, a chromaticity unevenness with respect to the film thickness unevenness may be reduced. In this case, in order that chromaticity of the pixel group A 1001 and chromaticity of the pixel group B 1002 have a complementary characteristic, it is necessary that a chromaticity coordinate variation with respect to the pixel film thickness variation increases in one of the pixel group A 1001 and the pixel group B 1002 while it decreases in the other.

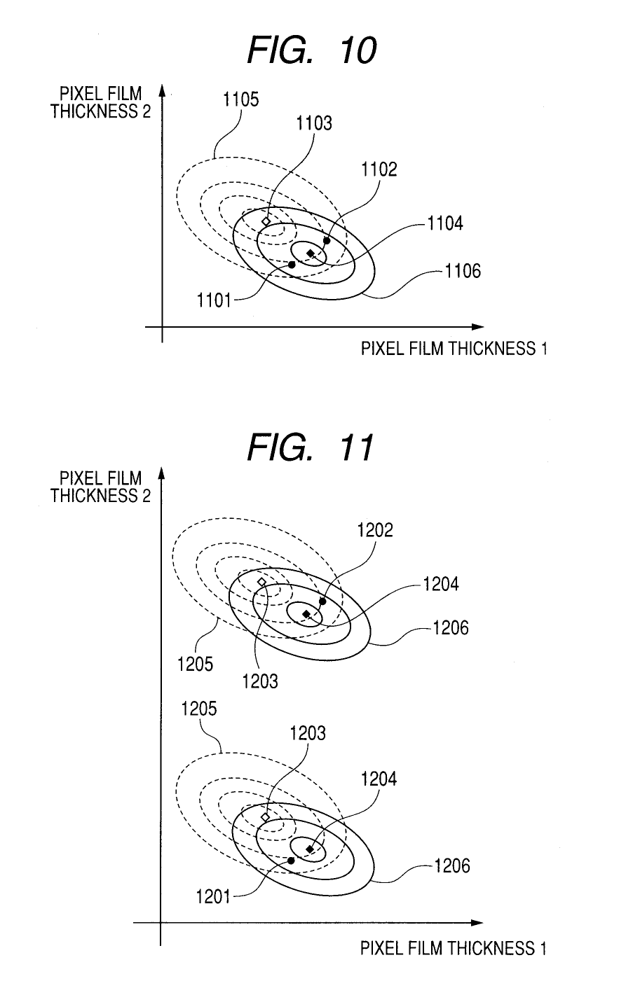

The description shows the case of one pixel film thickness, but actually, most device structures include two or more pixel film thicknesses (resonator structure). In this case, the pixel film thicknesses are assigned to two axes, for example, so as to consider a combination of the pixel groups satisfying the complementary characteristic by creating a contour graph concerning the luminance and the chromaticity as illustrated in FIG. 10. Here, it is assumed that the case giving one protruding shape in the luminance contour graph satisfies one interference condition. In order to realize the condition, the device structure satisfying the film thickness values of the pixel film thickness 1 and the pixel film thickness 2 giving the peak of the protruding shape is necessary.

FIG. 10 illustrates an example of the case where target coordinates of the chromaticity indicate the maximum value and the luminance and the chromaticity are made robust with respect to the film thickness unevenness. FIG. 10 is a contour graph with respect to two pixel film thicknesses. In FIG. 10, the pixel A is represented by reference numeral 1101; the pixel B, 1102; the maximum value of luminance, 1103; the target chromaticity, 1104; the contour graph of the luminance, 1105; and the contour graph of the chromaticity, 1106.

The pixel A 1101 and the pixel B 1102 sandwich the target chromaticity 1104 giving the maximum shape, and are set so as to have a film thickness structure in which the luminance varies gradually in a complementary manner with respect to the film thickness variation. It is not always necessary to sandwich the peak 1103 giving the maximum luminance, but it is necessary to set the pixel A and the pixel B on both ends on which the variation in luminance becomes a protruding shape. Thus, the luminance variation with respect to the film thickness unevenness may be suppressed while correcting the chromaticity variation.

In addition, the pixel A 1101 and the pixel B 1102 may be set with respect to each of two different maximum values (peaks of the protruding shapes). Here, the case where two protruding shapes are given in the contour graph 1105 of the luminance is considered as two interference conditions. As individual interference order numbers of “pixel film thickness 1, pixel film thickness 2”, two conditions such as “a, b” and “a, b+1” or “a, b” and “a+1, b” are considered. Note that the interference condition means the above-mentioned equation (3), and the interference order number corresponds to m in the equation (3).

For instance, FIG. 11 illustrates a contour graph with respect to the pixel film thickness when the pixel A and the pixel B are set with respect to different extreme values, in which the pixel film thickness 1 is fixed while the pixel film thickness 2 is increased and the interference order number concerning the pixel film thickness 2 is incremented by one so that two maximum values are considered. In FIG. 11, the pixel A is represented by reference numeral 1201; the pixel B, 1202; the maximum value of the luminance, 1203; the target chromaticity, 1204; the luminance contour graph, 1205; and the chromaticity contour graph, 1206.

The individual interference order numbers of “pixel film thickness 1, pixel film thickness 2” correspond to two of “a, b” and “a, b+1”. In this case, the pixel A 1201 is set to a thinner side than the film thickness structure at the interference order number (a, b) peak, and the pixel B 1202 is set to a thicker side than the film thickness structure of the interference order number (a, b+1) peak. As a reason for selecting this structure, it is considered that the pixel film thickness 2 (except for the pixel film thickness 1) includes the cathode and a wiring resistance may be reduced by increasing the thickness of the cathode. Similarly to the above description, it is not always necessary that the pixel A and the pixel B sandwich the peak 1203 giving the maximum luminance, but it is necessary to set the pixel A and the pixel B on both ends on which the luminance variation becomes a protruding shape.

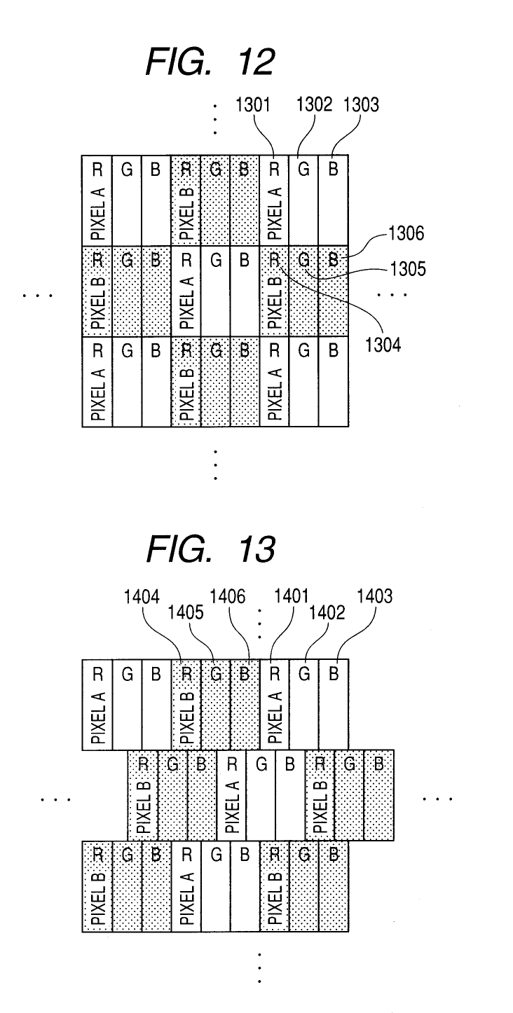

As to the arrangement of the pixel group A and the pixel group B in the image display apparatus according to the present invention, the pixel group A and the pixel group B may be arranged so as to be adjacent to each other for one pixel in plan view. If the pixel group A and the pixel group B are arranged to be adjacent to each other alternately, characteristics of the pixel group A and the pixel group B may be averaged effectively. For instance, in the case where the pixel arrangement is a stripe arrangement, if the pixel group A and the pixel group B are arranged in a checkered pattern as illustrated in FIG. 12, the pixel group A and the pixel group B may be arranged to be adjacent to each other alternately. FIG. 12 is an explanatory diagram of a plane arrangement example of the pixel group A and the pixel group B. In FIG. 12, a Red_pixel A is represented by reference numeral 1301; a Green_pixel A, 1302; a Blue_pixel A, 1303; a Red_pixel B, 1304; a Green_pixel B, 1305; and a Blue_pixel B, 1306.

In addition, there are currently considered various pixel arrangements other than the stripe arrangement, and there is no problem if the pixel group A and the pixel group B are arranged to be adjacent to each other substantially alternately in the same manner as in the checkered pattern. For instance, FIG. 13 illustrates an arrangement example of the pixel group A and the pixel group B in a delta arrangement. FIG. 13 is an explanatory diagram of a plane arrangement example of the pixel group A and the pixel group B. In FIG. 13, the Red_pixel A is represented by reference numeral 1401; the Green_pixel A, 1402; the Blue_pixel A, 1403; the Red_pixel B, 1404; the Green_pixel B, 1405; and the Blue_pixel B, 1406.

The image display apparatus of the present invention may be embodied in a high resolution pixel form that is equal to or higher than human visual recognition. Then, the state in which the pixel group A and the pixel group B vary in a complementary manner cannot be distinguished and recognized, and hence averaged light-emitting characteristics between the pixel group A and the pixel group B may be recognized substantially. What extent of resolution is actually adopted is determined based on an application specification, but 100 to 150 pixels per inch or higher resolution may be adopted in the case of a diagonal panel size of 3 inches, for example.

The pixel group A and the pixel group B in the image display apparatus of the present invention have different film thicknesses of at least one layer constituting the organic EL device. The layer to be varied so as to function in a complementary manner is determined by considering a process condition, tact, cost, and other conditions.

It is not necessary to apply the present invention to every color in the display region. The present invention may be applied to only a specific color. For instance, it is very effective to apply the present invention to only the green color that has a highest visual sensitivity considering process cost.

In addition, the effect of the present invention may be exerted on the entire display region, but there may be a case where the effect cannot be exerted completely due to characteristics of “luminance and chromaticity” determined from the device structure and a relationship between the set film thicknesses of the pixel group A and the pixel group B. However, compared with the case where the present invention is not applied, it is a matter of tuning operation how the characteristic unevenness may be suppressed without decreasing characteristic efficiency of the entire display region.

Next, the image display apparatus according to the embodiment of the present invention, particularly, a display panel portion is described. Based on a difference of a light extraction direction with respect to the substrate, the device structure is classified roughly into two types (bottom emission and top emission). In the case of the bottom emission structure, the glass substrate, the transparent electrode, the organic EL device, and the reflective electrode are usually disposed in this order so as to extract light that passes through the substrate. In addition, in the case of the top emission structure, the glass substrate, the reflective electrode, the organic EL device, and the transparent electrode are usually disposed in this order so as to extract light from the side opposite to the substrate. Each of the bottom emission structure and the top emission structure has an advantage and a disadvantage, and hence an appropriate structure is selected according to the application. The reflective electrode may be selected appropriately so as to satisfy a design specification without a problem even in the case of using a metal film or a combination of a transparent electrode and a metal film. Further, the side of the organic EL device that contacts with atmosphere is provided with a glass cap in which desiccant is disposed or a sealing film having a sufficient moisture resistance function, and hence atmosphere stability of the device may be secured.

These components are described in more detail. Glass, Si wafer, ceramic such as alumina, a transparent resin, stainless steel with an insulating film, or the like is used as the substrate constituting the organic EL device. In the case of the bottom emission structure, a member having good light transparency is used. Wiring for driving the device, a transistor portion, a sustaining capacitor portion for sustaining a gate voltage of a transistor in the drive device portion, and wiring for turning on each of the electronic devices are formed and arranged on the substrate by a photolithography process. Note that the wiring for driving the device includes a power supply line, a signal line, a selection line and a ground line, while the transistor portion includes the drive device portion and the selection device portion.

As an electrode of the organic EL device, the anode has a role of injecting holes into the hole-transporting layer, and it is effective to have a work function of 4.5 eV or higher. An anode material used in the present invention is not particularly limited, but an oxide transparent electrode material such as an indium-tin oxide alloy (ITO), indium oxide, or zinc oxide may be used.

As the cathode, a material having a small work function may be used for the purpose of injection of electrons into the electron-transporting band or emission layer. The cathode material is not particularly limited. Specific examples include indium, aluminum, magnesium, a magnesium-indium alloy, a magnesium-aluminum alloy, an aluminum-lithium alloy, an aluminum-scandium-lithium alloy, and a magnesium-silver alloy, and mixtures thereof. Here, as to these electrodes, one of the anode and the cathode is transparent in the visible light region while the other electrode has a high reflectivity. In addition, the thickness of these electrodes is not particularly limited as long as the electrodes perform the natural functions as electrodes, but preferably, the thickness is within the range from 0.02 to 2 μm.

The device structure of the organic EL emission portion according to the present invention is the structure in which one or two organic compound layers or more are stacked between the above-mentioned electrodes, and this structure is not interpreted as a limitation. As examples, the following five structures may be exemplified:

(1) anode, emission layer, cathode;

(2) anode, hole-transporting layer, emission layer, electron-transporting layer, cathode;

(3) anode, hole-transporting layer, emission layer, cathode;

(4) anode, emission layer, electron-transporting layer, cathode; and

(5) anode, hole-transporting layer, emission layer, electron-transporting layer, electron injection layer, cathode.

Organic compounds to be used in the hole-transporting layer, the emission layer, the electron-transporting layer, the hole injection layer, and the electron injection layer are not particularly limited and may be formed of low molecular materials, high molecular materials, or a combination thereof. Further, inorganic compounds may be used when required.

Examples of the compounds include the following.

A hole-transporting material may have excellent mobility for facilitating injection of a hole from an anode and for transporting the injected hole to an emission layer. Examples of low molecular weight materials and high molecular weight materials having hole-injection transporting property include, but are of course not limited to, a triarylamine derivative, a phenylenediamine derivative, a triazole derivative, an oxadiazole derivative, an imidazole derivative, a pyrazoline derivative, a pyrazolone derivative, an oxazole derivative, a fluorenone derivative, a hydrazone derivative, a stilbene derivative, a phthalocyanine derivative, a porphyrin derivative, poly(vinylcarbazole), poly(silylene), poly(thiophene), and other conductive polymers.

As the light-emitting material, fluorescent materials and phosphorescent materials having high emission efficiency are used. The light-emitting material of the present invention is not particularly limited and any compound generally used as a light-emitting material may be used. Examples include a tris(8-quinolinol)aluminum complex (Alq3), bis diphenyl vinyl biphenyl (BDPVBi), 1,3-bis(p-t-butylphenyl-1,3,4-oxadizolyl)phenylene (OXD-7), N,N′-bis(2,5-di-t-butylphenyl) perylene tetracarboxylic diimide (BPPC), and 1,4-bis(p-tolyl-p-methylstyrylphenylamino)naphthalene.

The electron-transporting material may be arbitrarily selected from materials which have a function of transporting the injected electron into the emission layer. The material is selected in consideration of, for example, the balance with the mobility of a carrier of the hole-transporting material. Examples of the material having electron-injection/transporting property include, but are of course not limited to, an oxadiazole derivative, an oxazole derivative, a thiazole derivative, a thiadiazole derivative, a pyrazine derivative, a triazole derivative, a triazine derivative, a perylene derivative, a quinoline derivative, a quinoxaline derivative, a fluorenone derivative, an anthrone derivative, a phenanthroline derivative, and an organometallic complex.

Examples of the hole injection material include transition metal oxide such as MoO3, WO3, and V2O5, and copper phthalocyanine (Cupc).

In addition, examples of the electron injection material include an alkali metal, an alkali-earth metal, a compound thereof, and the like. The electron injection material is contained in the above-mentioned electron-transporting material by a ratio within the range from 0.1 to several tens percent, and hence the electron injectability may be given. The electron injection layer is not necessarily an essential layer, but considering a damage that may be caused afterward in the film forming process for the transparent cathode, the electron injection layer of a thickness within the range from 10 to 100 nm may be inserted so that good electron injectability may be secured.

Further, as production methods for the anode, the hole-transporting layer, the emission layer, the electron-transporting layer, the hole injection layer, the electron injection layer, and the cathode, a vacuum evaporation method, an ionization-assisted evaporation method, sputtering, plasma, or a known coating method are generally used. Further, the anode, the hole-transporting layer, the emission layer, the electron-transporting layer, the hole injection layer, the electron injection layer, and the cathode may be formed using any known coating method (such as a spin coating, dipping, casting, LB, or inkjet method) in which a compound is dissolved in an appropriate solvent. However, for application of the present invention, it is required that the film thickness unevenness generated in the display region and the film thickness itself be accurately determined. In addition, only in the case where reproducibility of the film thickness unevenness and the value of the film thickness is obtained, the film forming method may be freely selected.

After the film forming of the anode, the hole-transporting layer, the emission layer, the electron-transporting layer, the hole injection layer, the electron injection layer, and the cathode, a protective layer is provided for the purpose of preventing contact with, for example, oxygen or moisture. Examples of the protective layer include a metal nitride film made of, for example, silicon nitride or silicon oxynitride, a metal oxide film made of, for example, tantalum oxide, and a diamond thin film. In addition, the examples include a polymer film made of, for example, a fluorine resin, poly(p-xylene), polyethylene, a silicone resin, or a polystyrene resin, and a photocurable resin. In the case of the top emission structure, the protective layer is formed on the light extraction side of the transparent cathode, and therefore there is a need to satisfy the required specifications of moisture permeability and transparency.

In addition, each device itself may be covered with, for example, glass, a gas impermeable film, or a metal, and packaged with a proper sealing resin. In addition, a desiccant may be incorporated into the protective layer for improving the moisture resistance.

### EXAMPLES

Hereinafter, examples of the present invention are described, but the present invention is not limited to the examples. In addition, the pixel region of the image display apparatus is exemplified in the detailed description, but the same is true for other pixel region portions.

The structure film thickness of the same color pixels in the organic EL device is fixed to one design value so as to form a film, and the formed film is regarded as a reference (hereinafter, referred to as Ref.). Further, two pixels that are complementary to the Ref. are regarded as the pixel A and the pixel B.

### Example 1

In Example 1, the luminance and the chromaticity were made robust with respect to the film thickness unevenness in the image display apparatus using the light-emitting device of only the green color.

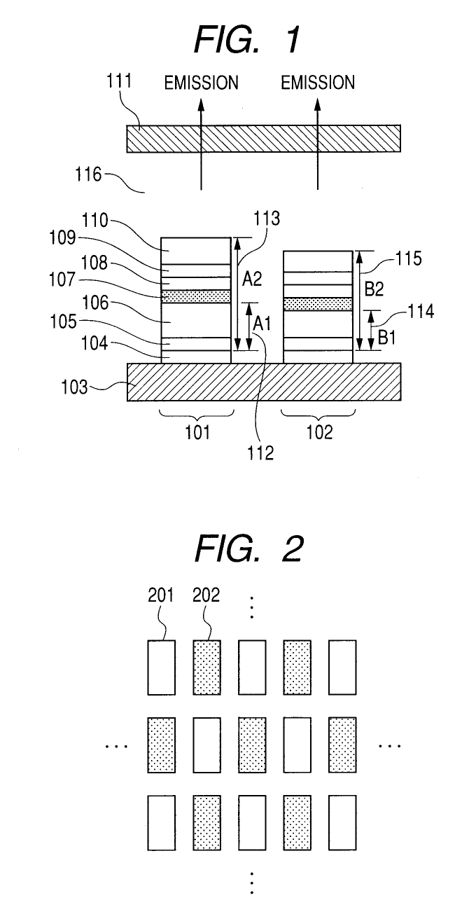

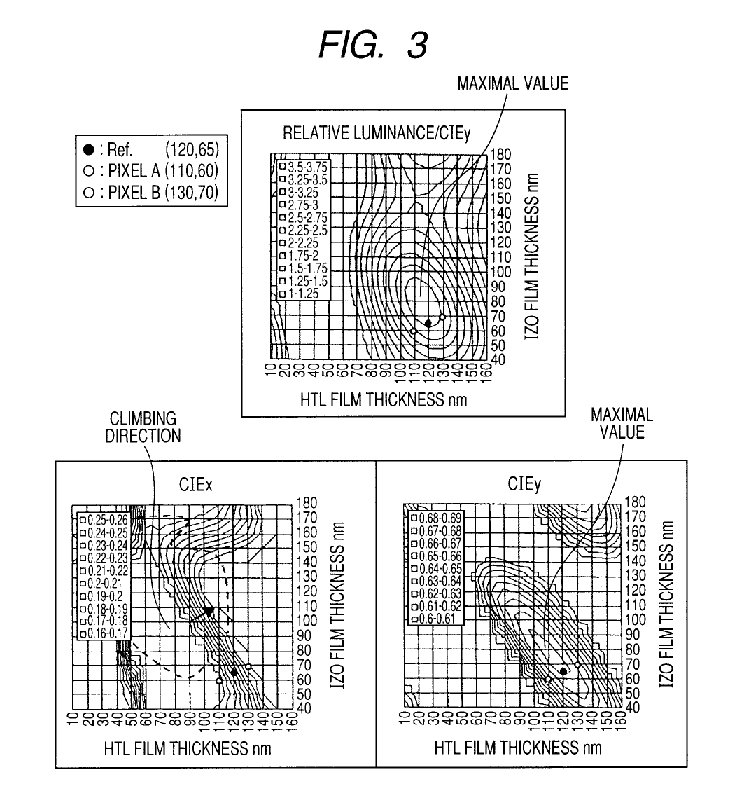

FIG. 1 illustrates a cross section of the organic EL device of the image display apparatus to which the present invention is applied. In addition, the film thickness structures of the Ref., the pixel group A, and the pixel group B used in this example are shown in Table 1 below. The film thickness of a hole-transporting layer 106 was changed in the region of the pixel film thickness 1, and the film thickness of a cathode layer 110 was changed in the region of the pixel film thickness 2. Hence, a pixel A 101 and a pixel B 102 were set. A relationship among the set film thicknesses of the Ref., the pixel group A and the pixel group B is shown in the relative luminance contour graph by optical simulation in FIG. 3.

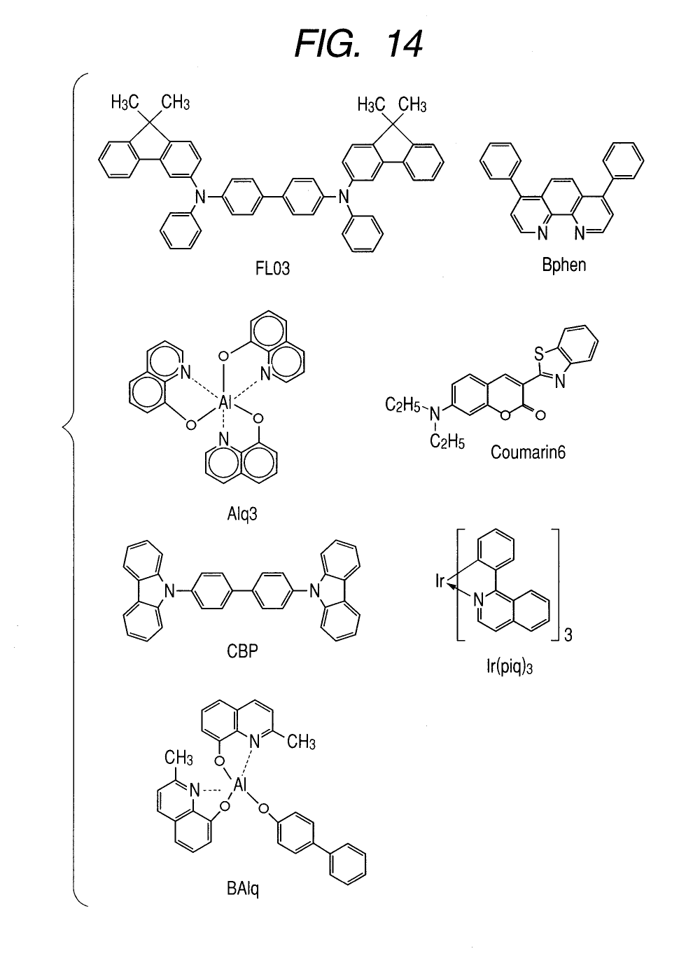

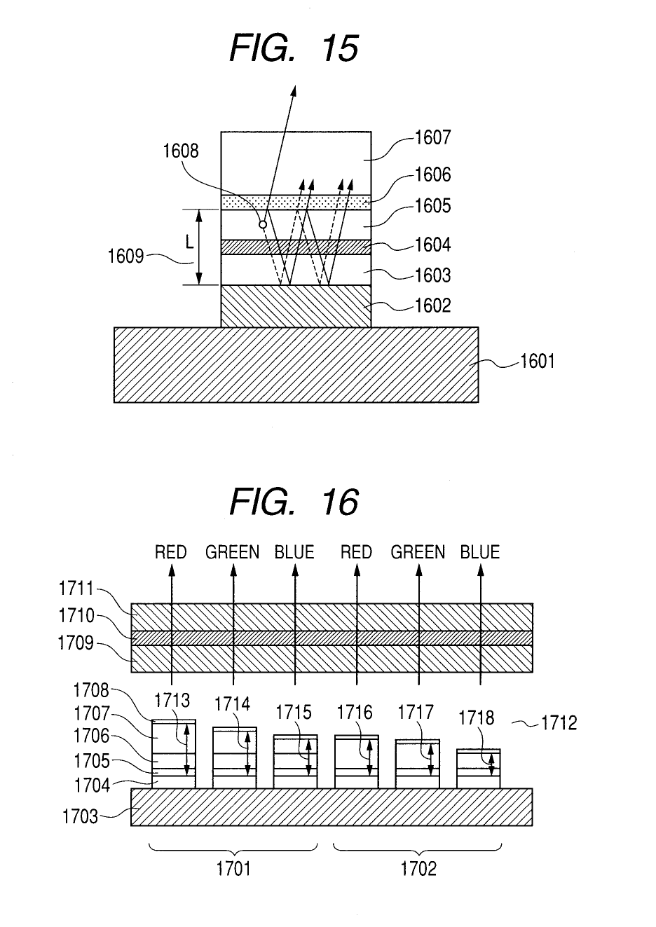

As the pixel arrangement, the display apparatus was manufactured as illustrated in FIG. 2, which has a pixel size of 60 μm×90 μm, a distance between pixels of 40 μm, 640×480 pixels and only green color. Pixels A 201 and pixels B 202 were arranged in a checkered pattern in each pixel so as to serve as the pixel group A and the pixel group B. As to the Ref., the same structure was adopted, in which 640×480 pixels of only green color were arranged. In addition, FIG. 14 illustrates chemical structural formulas of the organic materials that were used in this example.

As illustrated in FIG. 3, according to a chromaticity map with respect to the pixel film thickness, the target chromaticity of CIE y of the green color and its vicinity has the maximum value shape. Therefore, the pixel group A and the pixel group B were set in the region where the value of the “luminance/CIE y” does not change rapidly with respect to the film thickness unevenness. Specifically, the pixel group A and the pixel group B were set not just across the maximum value of the “luminance/CIE y” but on the contour line (isoline) or its vicinity. In this way, it was considered that both the luminance and the chromaticity were made complementary.

The above-mentioned organic EL display apparatus was manufactured by the following method. First, TFT drive circuits made of low temperature polysilicon were formed on the glass substrate as the support member. Wiring was laid so that current and signals corresponding to one pixel positional coordinates [X(i), Y(i)] may be supplied and controlled. Specifically, a ground line, a signal line, and a common power supply line were arranged along the long side of the pixel, and a scanning line was arranged along the short side of the pixel. A leveling film made of an acrylic resin was formed thereon so as to form a TFT substrate 103.

Further, Ag alloy (AgPdCu) as a reflective metal was formed thereon by the sputtering method to have a thickness of approximately 100 nm, and a reflective electrode 104 was patterned. A transparent conductive film ITO was formed by the sputtering method to have a thickness of 77 nm, and an anode layer 105 was patterned. Further, a device separation film was formed with an acrylic resin so as to prepare a substrate with an anode. This was cleaned by ultrasonic cleaning with isopropyl alcohol (IPA), and then dried after boil washing. After that, it was cleaned by UV/ozone cleaning, and film forming of the organic compound was performed by the vacuum evaporation.

A film of FLO3 was formed as the hole-transporting layer 106 on the cleaned anode layer 105. A shadow mask was used for separating film thicknesses of the pixel A and the pixel B. The film of 110 nm was formed as the hole-transporting layer of the pixel group A, and the film of 130 nm was formed as the hole-transporting layer of the pixel group B. A vacuum degree in this case was 1×10-4 Pa, and an evaporation rate was 0.2 nm/sec.

Next, a film of a green emission layer was formed as an organic emission layer 107 by using a shadow mask. As the green emission layer, Alq3 as host and light-emitting compound coumarin 6 were evaporated together so as to form the emission layer having a thickness of 40 nm. The film forming was performed in the condition of a vacuum degree of 1×10-4 Pa in the evaporation, and a film forming rate of 0.2 nm/sec.

Further, as a common electron-transporting layer 108, a film of bathophenanthroline (Bphen) was formed to have a film thickness of 10 nm by the vacuum evaporation method. The vacuum degree in the evaporation was 1×10-4 Pa, the film forming rate was 0.2 nm/sec. Next, Bphen and Cs2CO3 were evaporated together (at a weight ratio of 90:10) as a common electron injection layer 109, so as to have a film thickness of 20 nm. Vacuum degree in the evaporation was 3×10-4 Pa, and the film forming rate was 0.2 nm/sec.

The substrate on which film forming had been performed up to the electron injection layer 109 was moved to the sputtering device without breaking the vacuum, and an IZO film was formed as the cathode layer (transparent cathode) 110. The IZO film of the pixel A was formed to have a thickness of 60 nm, and the IZO film of the pixel B was formed to have a thickness of 70 nm. Further, a sealing glass substrate 111 having desiccant provided to the inside thereof was bonded to seal with sealing adhesive, and hence the organic EL display apparatus was obtained.

The film thickness values of the Ref. are shown in Table 1 below, in which the film thickness of the hole-transporting layer is 120 nm, the IZO film thickness of the cathode is 65 nm, and other film thicknesses are the same as those of the pixel A and the pixel B.

TABLE 1

| | | G pixel Ref | G pixel A | G pixel B |
|---|---|---|---|---|
| Layer | Material | (film thickness: nm) | (film thickness: nm) | (film thickness: nm) |
| Cathode | IZO | 65 | 60 | 70 |
| Electron | Bphen + Cs₂Co₃ | 20 | ← | ← |
| injection layer | | | | |
| Electron- | Bphen | 10 | ← | ← |
| transporting layer | | | | |
| Emission layer | ALQ + coumarin 6 | 40 | ← | ← |
| Hole- | FLO3 | 120 | 110 | 130 |
| transporting layer | | | | |
| Anode | ITO | 77 | ← | ← |

In the manufactured organic EL display apparatus, the drive signal programmed to have a rate of 16.7 msec per frame was input to the drive driver, and hence each pixel circuit supplied emission current to the organic EL device. Then, light emissions of the regions that were considered to be an upper limit value, an average value, and a lower limit value in each film thickness value of the pixel group A and the pixel group B were measured.

Results of the measurement of the Ref. item and the complementary item are shown in Table 2 below. As being complementary, an unevenness range of luminance with respect to the film thickness unevenness changed from 13.9% to 13.3% (unevenness ratio to an average value of itself), the unevenness range of the chromaticity was decreased from 0.105 to 0.082 of CIE x, and from 0.026 to 0.014 of CIE y. As being clear from the results, robustness of the luminance and the chromaticity was improved with respect to the film thickness unevenness.

TABLE 2

| | | Relative | CIE | CIE |
|---|---|---|---|---|
| | | luminance | 1931 x | 1931 y |
| Characteristic | Ref. | 48.1 | 0.212 | 0.678 |
| average | Complementary | 50.5 | 0.245 | 0.660 |
| Characteristic | Ref. | 6.7 | 0.105 | 0.026 |
| variation range | Complementary | 6.7 | 0.082 | 0.014 |

### Example 2

The method of manufacturing the light-emitting device according to Example 2 and the structure of the image display apparatus are similar to those of Example 1. However, the pixel A and the pixel B are not constituted so as to sandwich the one extreme value as illustrated in the map diagram of FIG. 3, but two different extreme values are set. Therefore, (HTL film thickness, IZO film thickness) is set to a combination of the pixel A (110, 60) and the pixel B (130, 205) as shown in Table 3 below. In this example, a cathode thickness of half the entire pixels of the display apparatus is increased, and hence a secondary effect of reducing wiring resistance is aimed.

TABLE 3

| | | G pixel Ref | G pixel A | G pixel B |
|---|---|---|---|---|
| Layer | Material | (film thickness: nm) | (film thickness: nm) | (film thickness: nm) |
| Cathode | IZO | 65 | 60 | 205 |
| Electron | Bphen + Cs₂Co₃ | 20 | ← | ← |
| injection layer | | | | |
| Electron- | Bphen | 10 | ← | ← |
| transporting layer | | | | |
| Emission layer | ALQ + coumarin 6 | 40 | ← | ← |
| Hole- | FLO3 | 120 | 110 | 130 |
| transporting layer | | | | |
| Anode | ITO | 77 | ← | ← |

In the manufactured organic EL display apparatus, the drive signal programmed to have a rate of 16.7 msec per frame was input to the drive driver, and hence each pixel circuit supplied emission current to the organic EL device. Then, light emissions of the regions that were considered to be an upper limit value, an average value, and a lower limit value in each film thickness value of the pixel group A and the pixel group B were measured.

Results of the measurement of the Ref. item and the complementary item are shown in Table 4 below. As being complementary, an unevenness range of luminance with respect to the film thickness unevenness was decreased from 13.9% to 13.2% (unevenness ratio to an average value of itself), the unevenness range width of the chromaticity was decreased from 0.105 to 0.085 of CIE x, and from 0.026 to 0.016 of CIE y. As being clear from the results, robustness of the luminance and the chromaticity was improved with respect to the film thickness unevenness. Further, in this example, reduction in power consumption was also observed due to reduction in wiring resistance of the cathode.

TABLE 4

| | | Relative | CIE | CIE |
|---|---|---|---|---|
| | | luminance | 1931 x | 1931 y |
| Characteristic | Ref. | 48.1 | 0.212 | 0.678 |
| average | Complementary | 50.1 | 0.240 | 0.655 |
| Characteristic | Ref. | 6.7 | 0.105 | 0.026 |
| variation range | Complementary | 6.6 | 0.085 | 0.016 |

### Example 3

In Example 3, an RGB full color image display apparatus was manufactured so that the complementary pixel groups (A and B) are set only in the green color devices. A panel size is 3 inches of QVGA (150 pixels per inch), in which three color devices of 320 pixels in row and 240 pixels in column are arranged as a stripe arrangement. An emission area is set to have 40% aperture based on a device separation film between colors, a BM arrangement and the like. A method of manufacturing the light-emitting device and a fundamental structure of the image display apparatus are similar to those of Example 1. A specific film thickness structure of a red color device is shown in Table 5 below, a specific film thickness structure of a green color device is shown in Table 6 below, and a specific film thickness structure of a blue color device is shown in Table 7 below.

TABLE 5

| | | R pixel Ref |
|---|---|---|
| Layer | Material | (film thickness: nm) |
| Cathode | IZO | 60 |
| Electron injection layer | Bphen + Cs₂Co₃ | 20 |
| Electron-transporting layer | Bphen | 10 |
| Emission layer | CBP + Ir(piq)₃ | 30 |
| Hole-transporting layer | FLO3 | 190 |
| Anode | ITO | 80 |

TABLE 6

| | | G pixel Ref | G pixel A | G pixel B |
|---|---|---|---|---|
| Layer | Material | (film thickness: nm) | (film thickness: nm) | (film thickness: nm) |
| Cathode | IZO | 60 | 55 | 65 |
| Electron | Bphen + Cs₂Co₃ | 20 | ← | ← |
| injection layer | | | | |
| Electron- | Bphen | 10 | ← | ← |
| transporting layer | | | | |
| Emission layer | ALQ + coumarin 6 | 40 | ← | ← |
| Hole- | FLO3 | 130 | ← | ← |
| transporting layer | | | | |
| Anode | ITO | 80 | 70 | 90 |

TABLE 7

| | | B pixel Ref |
|---|---|---|
| Layer | Material | (film thickness: nm) |
| Cathode | IZO | 55 |
| Electron injection layer | Bphen + Cs₂Co₃ | 20 |
| Electron-transporting layer | Bphen | 10 |
| Emission layer | Balq | 35 |
| Hole-transporting layer | FLO3 | 80 |
| Anode | ITO | 70 |

In the manufactured organic EL display apparatus, the drive signal programmed to have a rate of 16.7 msec per frame was input to the drive driver, and hence each pixel circuit supplied emission current to the organic EL device. Then, light emissions of the green color of the regions that were considered to be an upper limit value, an average value, and a lower limit value in each film thickness value of the pixel group A and the pixel group B were measured. Table 8 below shows measured data concerning the unevenness range of the relative luminance and the chromaticity.

TABLE 8

| | | Relative | CIE | CIE |
|---|---|---|---|---|
| | | luminance | 1931 x | 1931 y |
| Characteristic | ref. | 14.9% | 0.107 | 0.055 |
| variation range | Complementary | 11.3% | 0.082 | 0.038 |

Results of the measurement of the Ref. item and the complementary item were compared. As being complementary, an unevenness range of luminance with respect to the film thickness unevenness was decreased from 14.9% to 11.3% (decrease of 3.6%), the unevenness range of the chromaticity was decreased from 0.107 to 0.082 of CIE x, and from 0.055 to 0.038 of CIE y. In this way, as being complementary, robustness of the luminance and the chromaticity was improved with respect to the film thickness unevenness.

In this way, the RGB full color image display apparatus was manufactured, in which the light-emitting characteristics of the green color having high visual sensitivity were made robust.

In order to reduce cost of an image display apparatus such as a display or a monitor, it is inevitable that a mother substrate becomes large. This is true also for the organic EL display apparatus, but it is very difficult to form the thin film device such as the organic EL device uniformly in a large area. However, according to the image display apparatus of the present invention, yield may be improved without developing or introducing a new device or technique. The image display apparatus of the present invention has high potential to be developed as a technique for solving a manufacturing problem with the organic EL device.

While the present invention has been described with reference to exemplary embodiments, it is to be understood that the invention is not limited to the disclosed exemplary embodiments. The scope of the following claims is to be accorded the broadest interpretation so as to encompass all such modifications and equivalent structures and functions.

This application claims the benefit of Japanese Patent Application No. 2009-134064, filed Jun. 3, 2009, which is hereby incorporated by reference herein in its entirety.

What is claimed is:

1. An image display apparatus using an organic EL device, comprising emission pixels in which an organic compound layer is provided between a reflective electrode and a transparent electrode so that emitted light interferes between the reflective electrode and the transparent electrode,
wherein an arbitrary one of the emission pixels comprises pixel groups (A and B) which have two characteristics and have a combination of film thicknesses in which:
one of the film thicknesses is smaller and another one of the film thicknesses is larger than a film thickness at a peak of a curve in a protruding shape given by an intensity variation of emission luminance with respect to a film thickness variation of the emission pixel; and
the one of the film thicknesses is smaller and the another one of the film thicknesses is larger than a film thickness at a peak of a curve in a protruding shape given by a chromaticity variation of at least one component of chromaticity (CIE x, CIE y) with respect to the film thickness variation of the emission pixel.

2. The image display apparatus using an organic EL device according to claim 1, wherein the film thickness at the peak of the curve in the protruding shape given by the intensity variation of the emission luminance comprises one type of film thickness satisfying an interference condition.

3. The image display apparatus using an organic EL device according to claim 1, wherein the film thickness at the peak of the curve in the protruding shape given by the intensity variation of the emission luminance comprises two types of film thickness satisfying an interference condition, and one of the emission pixels has a smaller film thickness than one of the two types of film thickness while another one of the emission pixels has a larger film thickness than another one of the two types of film thickness.

4. The image display apparatus using an organic EL device according to claim 1, wherein the pixel groups (A and B) having the two characteristics are arranged alternately in one of a checkered pattern and a pattern similar to the checkered pattern in each emission pixel in plan view.

5. The image display apparatus using an organic EL device according to claim 1, wherein the chromaticity variation of the at least one component of the chromaticity (CIE x, CIE y) with respect to the film thickness variation of the emission pixel comprises a variation in CIE y of green color.
